(19) United States
(12) Patent Application Publication
(10) Pub. No.: US 2018/0242443 A1
(43) Pub. Date: Aug. 23, 2018

(54) WIRING BOARD AND METHOD OF MANUFACTURING WIRING BOARD

(71) Applicant: FUJITSU LIMITED, Kawasaki-shi (JP)

(72) Inventors: Megumi Tanaka, Kawasaki (JP); YOSHINORI MESAKI, YOKOHAMA (JP)

(73) Assignee: FUJITSU LIMITED, Kawasaki-shi (JP)

(21) Appl. No.: 15/886,900

(22) Filed: Feb. 2, 2018

(30) Foreign Application Priority Data
Feb. 20, 2017 (JP) 2017-028884

(51) Int. Cl. H05K 1/02; H05K 1/03; D03D 1/00; D03D 15/00; D06N 3/00; D06N 3/12; D06M 11/77; H05K 3/00

(52) U.S. Cl. CPC H05K 1/024; H05K 1/0245; H05K 1/038; H05K 1/0306; D03D 1/0082; D10B 2505/00; D06N 3/0006; D06N 3/12; D06N 3/0093; D06M 11/77; H05K 3/0011; D03D 15/0011

(57) ABSTRACT

A wiring board includes a core, and a differential signal wire disposed on a surface of the core, wherein the core includes a glass cloth formed such that a warp yarn and a weft yarn that are each formed of a glass fiber are woven, a resin in which the glass cloth is embedded, and a powder that disperses in a stitch of the glass cloth that is surrounded by the warp yarn and the weft yarn and that is formed of a material having a relative permittivity more than a relative permittivity of the resin.

### CROSS-REFERENCE TO RELATED APPLICATION

This application is based upon and claims the benefit of priority of the prior Japanese Patent Application No. 2017-28884, filed on Feb. 20, 2017, the entire contents of which are incorporated herein by reference.

### FIELD

The embodiment discussed herein is related to a wiring board and a method of manufacturing the wiring board.

### BACKGROUND

A known technique for controlling the relative permittivity of a wiring board is as follows.

For example, a known multilayer sheet includes a prepreg that uses a woven glass fiber fabric whose relative permittivity is 4.3 to 4.7 as a reinforcement and that uses a thermosetting resin composition containing a fine glass powder whose relative permittivity is 6.4 to 9.0 as a matrix resin.

A known wiring board including a core layer that includes an insulating base material containing a glass cloth and differential signal wires includes a filler at a position at which the filler reduces a difference in the relative permittivity between regions that affect transmission characteristics of the differential signal wires.

In the case where a differential signal is transmitted at a bit rate of, for example, more than 1 Gbps through a pair of the differential signal wires, a difference in delay (skew) between a positive signal (referred to below as a POS signal) and a negative signal (referred to below as a NEG signal) is a problem. An increased difference in delay between the POS signal and the NEG signal inversely affects the quality of signal transmission. One of the reasons why the difference in delay between the POS signal and the NEG signal occurs is a difference in length between the differential signal wires. In view of this, a tolerance is set for the difference in length between the differential signal wires in accordance with the bit rate at which the differential signal is transmitted so that the difference in delay between the POS signal and the NEG signal is reduced.

However, in some cases where the core of the wiring board in which the differential signal wires are formed contains the glass cloth, the difference in delay between the POS signal and the NEG signal is not sufficiently reduced in a manner to merely reduce the difference in length between the differential signal wires.

The followings are reference documents.
[Document 1] Japanese Laid-open Patent Publication No. 2005-15729 and
[Document 2] Japanese Laid-open Patent Publication No. 2009-259879.

### SUMMARY

According to an aspect of the invention, a wiring board includes a core, and a differential signal wire disposed on a surface of the core, wherein the core includes a glass cloth formed such that a warp yarn and a weft yarn that are each formed of a glass fiber are woven, a resin in which the glass cloth is embedded, and a powder that disperses in a stitch of the glass cloth that is surrounded by the warp yarn and the weft yarn and that is formed of a material having a relative permittivity more than a relative permittivity of the resin.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a plan view of an example of the structure of a glass cloth,

FIG. 1B is a sectional view of a wiring board taken along line 1B-1B in FIG. 1A;

FIG. 2A is a plan view of an example of the positional relationship between the glass cloth and differential signal wires;

FIG. 2B is a plan view of an example of the positional relationship between the glass cloth and the differential signal wires;

FIG. 3 is a plan view of an example of the positional relationship between the glass cloth and meandering differential signal wires;

FIG. 4 is a sectional view of a wiring board that uses opening glass cloths;

FIG. 5 is a sectional view of a wiring board including a core containing two glass cloths;

FIG. 6A is a sectional view of the structure of a wiring board according to an embodiment;

FIG. 6B is a sectional view of the structure of the wiring board according to the embodiment;

FIG. 7 is a plan view of a glass cloth included in the wiring board according to the embodiment;

FIG. 8A illustrates a method of manufacturing the wiring board according to the embodiment;

FIG. 8B illustrates the method of manufacturing the wiring board according to the embodiment;

FIG. 8C illustrates the method of manufacturing the wiring board according to the embodiment;

FIG. 8D illustrates the method of manufacturing the wiring board according to the embodiment;

FIG. 8E illustrates the method of manufacturing the wiring board according to the embodiment;

FIG. 8F illustrates the method of manufacturing the wiring board according to the embodiment;

FIG. 8G illustrates the method of manufacturing the wiring board according to the embodiment;

FIG. 8H illustrates the method of manufacturing the wiring board according to the embodiment;

FIG. 8I illustrates the method of manufacturing the wiring board according to the embodiment;

FIG. 8J illustrates the method of manufacturing the wiring board according to the embodiment;

FIG. 9 is a sectional view of the structure of a model board that is a simulation model;

FIG. 10 is a graph illustrating frequency characteristics of insertion loss that is obtained by simulation for each relative permittivity of a second core; and

FIG. 11 is a sectional view of the structure of a wiring board for measurement manufactured in a conventional manner.

### DESCRIPTION OF EMBODIMENT

A problem in the case where glass cloths are used for cores of a wiring board will be first described.

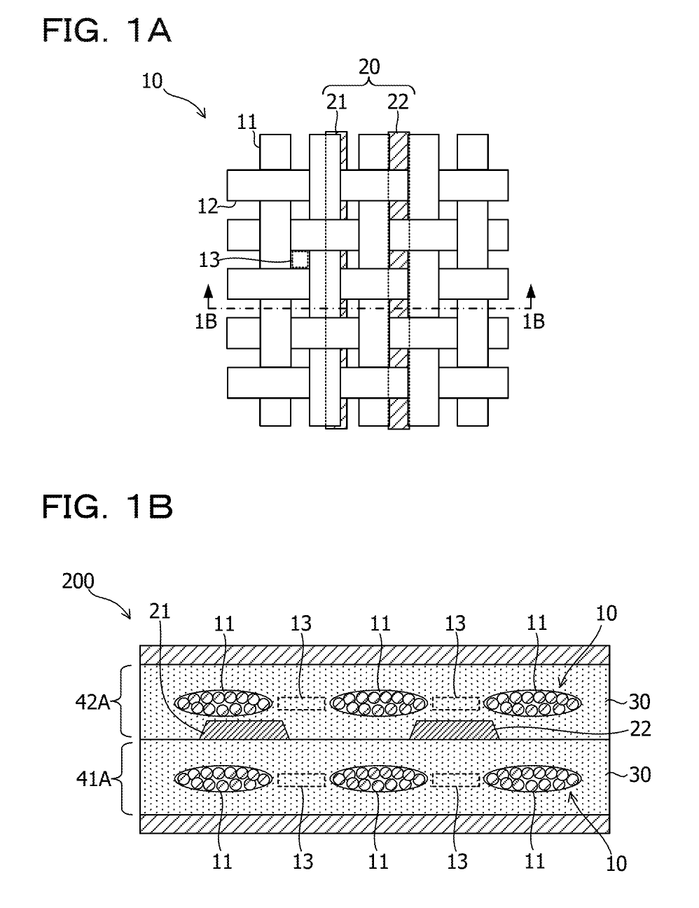

FIG. 1A is a plan view of an example of the structure of one of glass cloths 10 used for the cores of the wiring board. Each of the glass cloths 10 is formed such that warp yarns 11 and weft yarns 12 formed of glass fibers are woven. The glass cloth 10 includes regions that contain no glass fibers in stitches 13 surrounded by the warp yarns 11 and the weft yarns 12. In an example illustrated in FIG. 1A, a POS signal is transmitted through a wire (referred to below as a POS wire) 21 of differential signal wires 20 that extends in a direction in which the warp yarns 11 extend and that is disposed directly under the warp yarns 11. A NEG signal is transmitted through a wire (referred to below as a NEG wire) 22 of the differential signal wires 20 that extends in the direction in which the warp yarns 11 extend and that is disposed directly under some of the stitches 13 at which there are no warp yarns 11.

FIG. 1B is a sectional view of a wiring board 200 taken along line 1B-1B in FIG. 1A. The wiring board 200 is formed of cores 41A and 42A that are stacked and that contain thermosetting resins 30 in which the glass cloths 10 are embedded.

The relative permittivity of the glass fibers included in each glass cloth 10 is about 6. The relative permittivity is about 3 in the case where the thermosetting resins 30 extending around the glass cloths 10 are, for example, epoxy resins. The transmission rate v of the POS signal and the NEG signal can be expressed as the following expression (1):

v=k·C/εr^{1/2} (1),

where εr is a relative permittivity near the POS wire 21 and the NEG wire 22, c is the speed of light, and k is a fixed number.

As expressed as the expression (1), the transmission rate v of the POS signal and the NEG signal is affected by the relative permittivity εr near the POS wire 21 and the NEG wire 22. Accordingly, in the case where the POS wire 21 is disposed directly under the warp yarns 11, and the NEG wire 22 is disposed directly under some of the stitches 13 at which there are no warp yarns 11 as illustrated in FIG. 1A and FIG. 1B, a difference in delay between the POS signal and the NEG signal occurs.

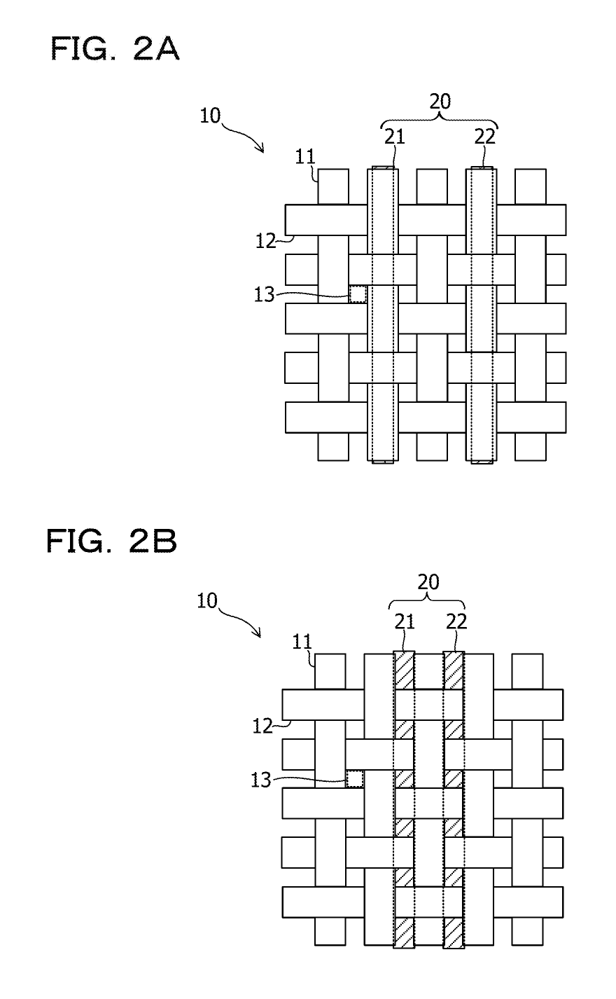

In view of this, as illustrated in FIG. 2A and FIG. 2B, a conceivable countermeasure, for example, is to determine the arrangement of the POS wire 21 and the NEG wire 22 in accordance with the arrangement of the warp yarns 11 and the weft yarns 12 of the glass cloths 10. However, the arrangement of the warp yarns 11 and the weft yarns 12 differs between the cores, and accordingly, it is desirable to grasp the arrangement of the warp yarns 11 and the weft yarns 12 by using, for example, X-ray observation before the POS wire 21 and the NEG wire 22 are arranged. This greatly reduces the productivity of the wiring board.

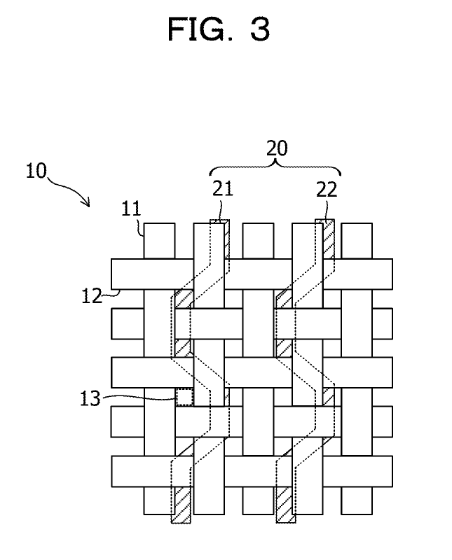

Another conceivable countermeasure is to cause the POS wire 21 and the NEG wire 22 to meander as illustrated in FIG. 3 to substantially equalize the relative permittivity near the wires. In this case, however, it is difficult to minimize the length of the POS wire 21 and the NEG wire 22, and signal delays occur. In addition, spaces for the meander of the POS wire 21 and the NEG wire 22 are ensured, and the area efficiency of the POS wire 21 and the NEG wire 22 decreases.

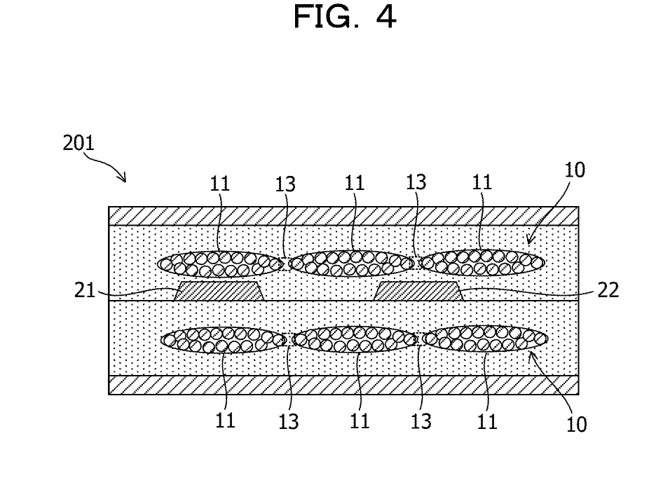

FIG. 4 is a sectional view of a wiring board 201 that uses opening glass cloths as the glass cloths 10. The opening glass cloths are characterized in that the distance between the warp yarns and the distance between the weft yarns are shorter than those in a typical glass cloth and the stitches 13 are small. In the wiring board 201 that uses the opening glass cloths, a difference between the relative permittivity near the POS wire 21 and the relative permittivity near the NEG wire 22 is smaller than that in a wiring board that uses typical glass cloths, and a difference in delay between the POS signal and the NEG signal is small. Because of these characteristics, the opening glass cloths are used in a wiring board in which a signal is transmitted at a bit rate of, for example, more than 10 Gbps.

However, in the wiring board 201 that uses the opening glass cloths, the density of the glass fibers in the stitches 13 is lower than the density of the glass fibers in portions at which there are the warp yarns 11 and the weft yarns 12. For this reason, in the case where a signal is transmitted at a bit rate of, for example, more than 25 Gbps, it is difficult for the wiring board 201 that uses the opening glass cloths to reduce the difference in delay between the POS signal and the NEG signal to an acceptable level.

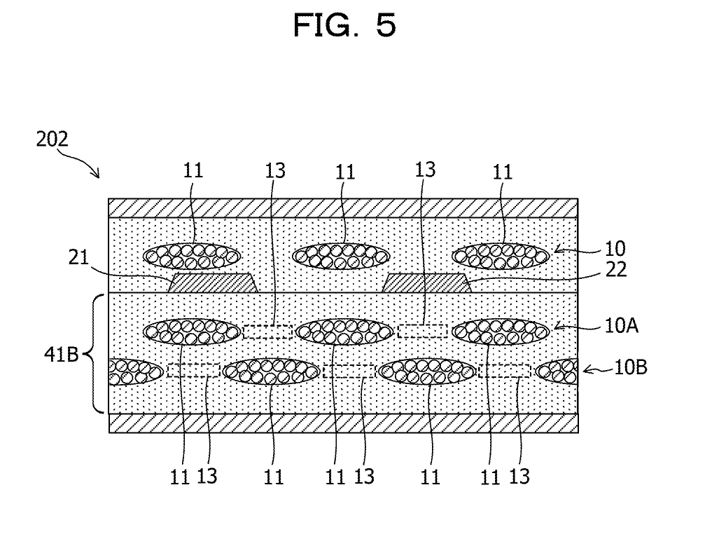

Another conceivable measure for equalizing the relative permittivity near the POS wire 21 and the relative permittivity near the NEG wire 22 is to use a core 41B containing two glass cloths 10A and 10B as in a wiring board 202 illustrated in FIG. 5. In the core 41B, the two glass cloths 10A and 10B are stacked such that the glass fibers in the glass cloth 10B in a lower layer are disposed directly under the stitches 13 in the glass cloth 10A in an upper layer. In the case where the two glass cloths 10A and 10B are stacked in the core 41B in the above manner, the difference between the relative permittivity near the POS wire 21 and the relative permittivity near the NEG wire 22 can be reduced.

However, it is not easy to manufacture the core 41B in which the two glass cloths 10A and 10B are thus stacked, and it is difficult to stably manufacture the wiring board 202 illustrated in FIG. 5.

Thus, it is difficult for a wiring board including glass cloths to stably reduce the difference between the relative permittivity near the POS wire and the relative permittivity near the NEG wire without limiting the arrangement of the POS wire and the NEG wire. Consequently, it is difficult for a wiring board used for transmitting a signal at a bit rate of, for example, more than 25 Gbps to reduce the difference in delay between the POS signal and the NEG signal to an acceptable level.

An embodiment will now be described with reference to the drawings. In the drawings, components or parts that are the same or equivalent to each other are designated by like reference numbers.

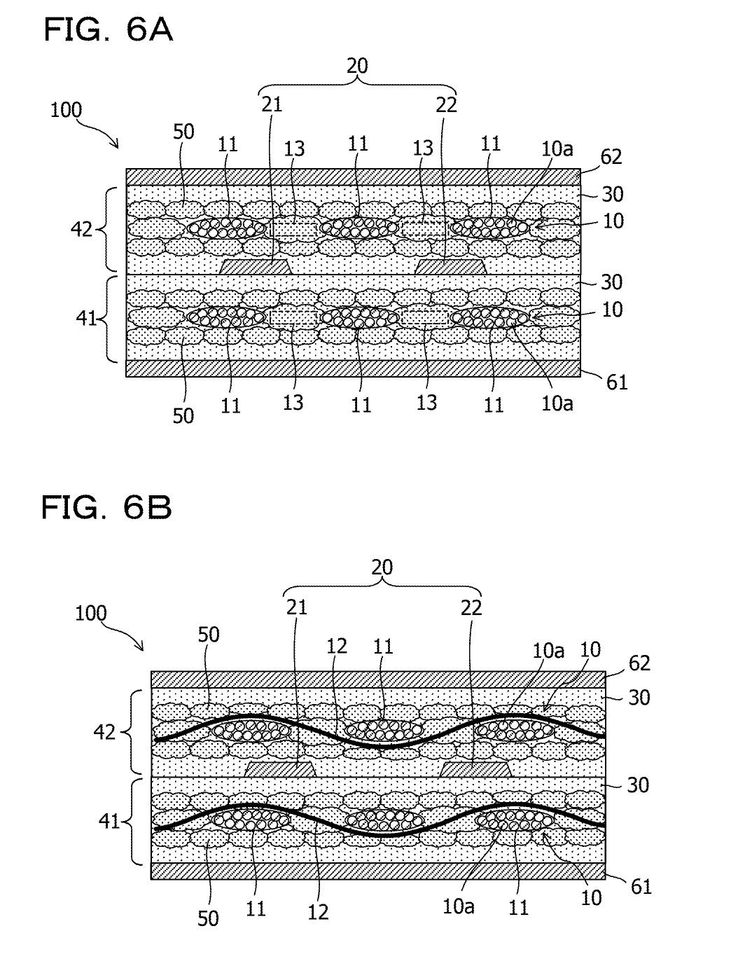

FIG. 6A and FIG. 6B are sectional views of a wiring board 100 according to the embodiment. The wiring board 100 includes the two cores 41 and 42 and the differential signal wires 20 that are disposed near a joint between the core 41 and the core 42 and that include the POS wire 21 and the NEG wire 22.

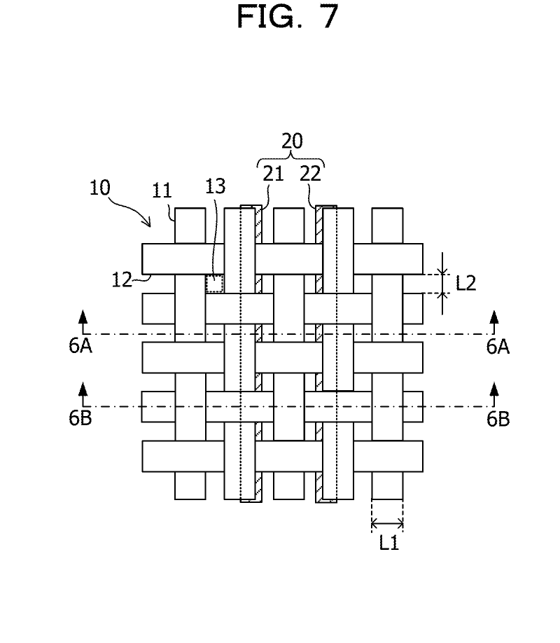

In the cores 41 and 42, the glass cloths 10 are embedded in the respective thermosetting resins 30 such as epoxy resins. Each thermosetting resin 30 is not limited to an epoxy resin and may be another resin that can be used as a base material of the wiring board. FIG. 7 is a plan view of one of the glass cloths 10 included in the cores 41 and 42. The glass cloth 10 is formed such that the warp yarns 11 and the weft yarns 12 that contain bundles of glass fibers 10a (see FIG. 6A and FIG. 6B) are woven in the form of, for example, a plain weave.

Each of the glass cloths 10 includes the stitches 13 surrounded by the warp yarns 11 and the weft yarns 12. In each stitch 13, there are no glass fibers 10a. The width L1 of each warp yarn 11 and each weft yarn 12 of the glass cloth 10 is, for example, about 450 μm. The length L2 of a side of each stitch 13 is, for example, about 150 μm. The diameter of each glass fiber 10a that forms the warp yarns 11 and the weft yarns 12 is about 4 μm to 7 μm.

FIG. 6A corresponds to a section along line VIA-VIA in FIG. 7 and illustrates a section along some of the stitches 13 of the glass cloths 10. Accordingly, FIG. 6A illustrates the warp yarns 11 of the glass cloths 10 but does not illustrate the weft yarns 12. As illustrated in FIG. 6A, in the cores 41 and 42, glass powders 50 spread over the upper surface and the lower surface of each glass cloth 10. The particle diameter of each glass powder 50 is preferably smaller than the diameter of each glass fiber 10a that forms the warp yarns 11 and the weft yarns 12 of the glass cloths 10 and is more preferably, for example, 3 μm or less. The glass powders 50 spread over the entire upper surface and the entire lower surface of each glass cloth 10, and disperse in the stitches 13 of each glass cloth 10.

The relative permittivity of the thermosetting resins 30 extending around the glass cloths 10 in the cores 41 and 42 is about 3. The relative permittivity of glass of which the glass fibers 10a are formed is about 6. The glass powders 50 are formed of the same kind of glass material as the glass of which the glass fibers 10a are formed. The relative permittivity of the glass powders 50 is substantially equal to the relative permittivity of the glass fibers 10a.

FIG. 6B corresponds to a section along line VIB-VIB in FIG. 7. That is, FIG. 6B illustrates a section along one of the weft yarns 12 of each glass cloth 10 of the wiring board 100. As illustrated in FIG. 6B, in the cores 41 and 42, the glass powders 50 spread also to region in which the weft yarns 12 of the glass cloths 10 extend. According to the embodiment, the glass powders 50 are unevenly distributed near the glass cloths 10 in the cores 41 and 42.

Conductive films 61 and 62 each formed of a conductor such as copper are formed on surfaces of the cores 41 and 42. That is, the conductive films 61 and 62 interpose the differential signal wires 20 therebetween. A ground potential is applied to the conductive films 61 and 62. The conductive films 61 and 62 function as ground planes. According to the embodiment, the wiring board 100 forms a stripline.

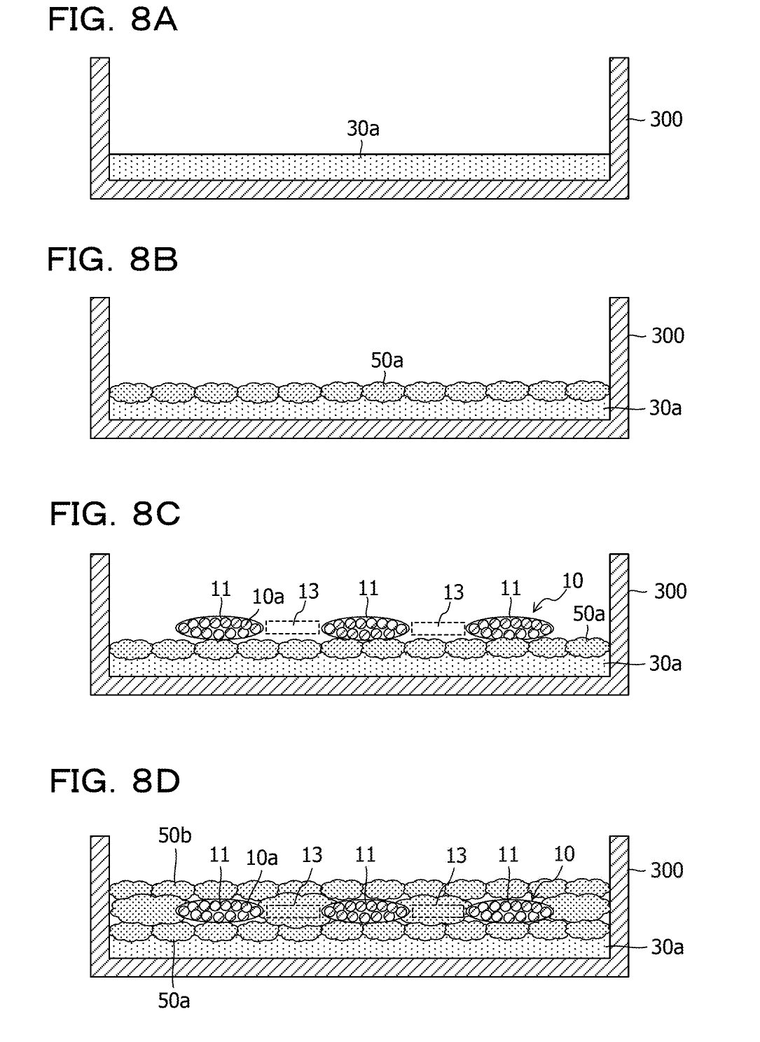

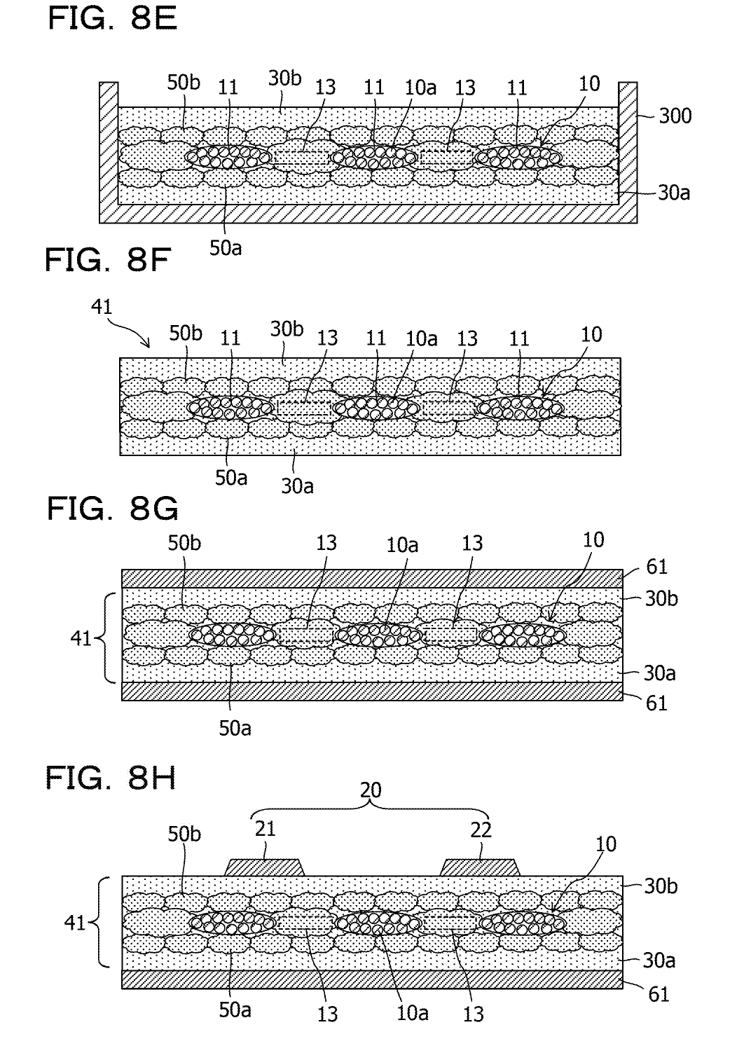

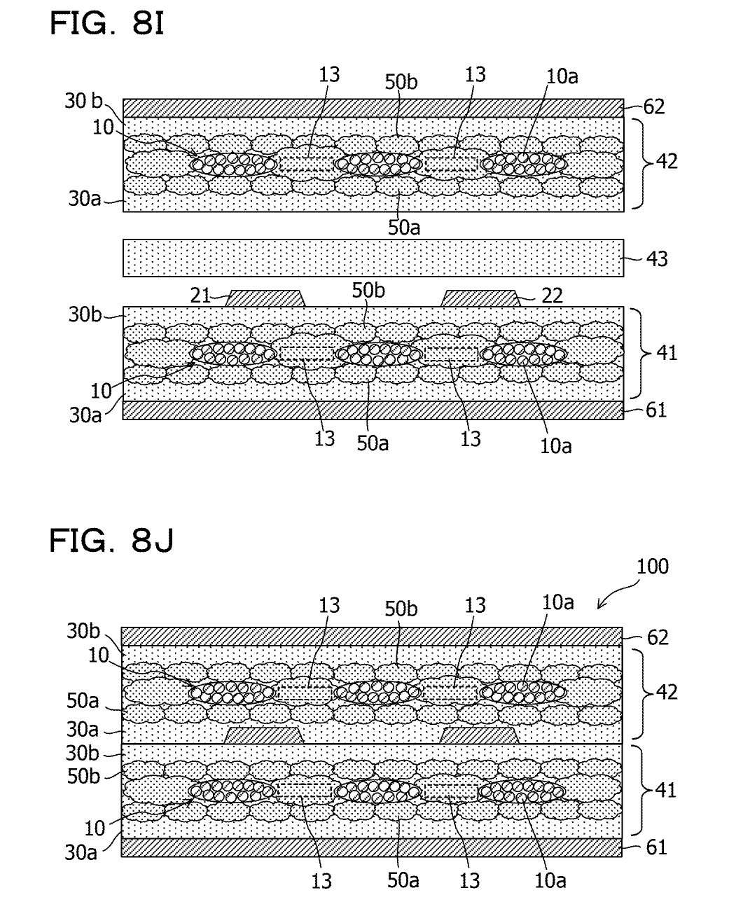

An example of a method of manufacturing the wiring board 100 will now be described with reference to FIG. 8A to FIG. 8I. A thermosetting resin 30a such as an epoxy resin is first poured into a frame 300. Subsequently, the thermosetting resin 30a is dried and semi-cured (see FIG. 8A).

Subsequently, a glass powder 50a is spread over an entire surface of the semi-cured thermosetting resin 30a (see FIG. 8B). In the case where the thermosetting resin 30a is semi-cured, the glass powder 50a does not disperse into the thermosetting resin 30a but remains on the surface of the thermosetting resin 30a. The diameter of the glass powder 50a is preferably smaller than the diameter of the glass fibers 10a included in the warp yarns 11 and the weft yarns 12 of the glass cloths 10 and is more preferably, for example, equal to or less than 3 μm.

Subsequently, one of the glass cloths 10 is placed on the glass powder 50a (see FIG. 8C). Subsequently, a glass powder 50b is spread over surfaces of the glass cloth 10. The particle diameter and material of the glass powder 50b are the same as in the glass powder 50a. The particle diameter of the glass powder 50b is sufficiently smaller than the size of each of the stitches 13 of the glass cloth 10, and accordingly, the glass powder 50b enters the stitches 13 of the glass cloth 10 and disperses (see FIG. 8D).

Subsequently, a thermosetting resin 30b is poured from above the glass powder 50b (see FIG. 8E). The material of the thermosetting resin 30b is the same as the thermosetting resin 30a. Subsequently, the thermosetting resins 30a and 30b are pressed and heated to cure the thermosetting resins 30a and 30b. Thus, the core 41 is formed (see FIG. 8F).

Subsequently, conductive films 61 each formed of a conductor such as copper foil are attached to the upper surface and the lower surface of the core 41 by using, for example, thermo-compression bonding. Thus, a copper-clad multilayer sheet is formed (see FIG. 8G).

Subsequently, the differential signal wires 20 including the POS wire 21 and the NEG wire 22 are formed on one of the surfaces of the core 41 in a manner in which one of the conductive films 61 formed on the surface of the core 41 is patterned by etching (see FIG. 8H).

Subsequently, the other core 42 is manufactured and prepared through the same processes as the core 41 is manufactured. A conductive film 62 formed of a conductor such as copper foil is formed on one of the surfaces of the core 42. Subsequently, the core 41 on which the conductive film 61 and the differential signal wires including the POS wire 21 and the NEG wire 22 are formed is bonded to the core 42 on which the conductive film 62 is formed with a prepreg 43 interposed therebetween (see FIG. 8I). Through the above processes, the wiring board 100 is formed (see FIG. 8J).

In the example of the manufacturing method, the conductive films 61 are attached to the surfaces of the core 41 to form the copper-clad multilayer sheet after the thermosetting resins 30a and 30b are cured. However, the method is not limited to the example. For example, a multilayer body including the conductive films 61, the thermosetting resins 30a and 30b, and the glass cloth 10 may be pressed and heated to form the copper-clad multilayer sheet after the conductive films 61 are formed on the surfaces of the semi-cured thermosetting resins 30a and 30b. This method enables curing of the thermosetting resins 30a and 30b and compression bonding of the conductive films 61 to be performed at the same time.

In the wiring board 100 according to the embodiment, the glass powders 50 disperse in the stitches 13 of the glass cloths 10 embedded in the cores 41 and 42 that interpose the differential signal wires 20 therebetween. Thus, the relative permittivity of the stitches 13 at which there are no glass fibers 10a can be close to the relative permittivity of portions at which there are the glass fibers 10a in a plane of each glass cloth 10. The glass powders 50 spread over the entire upper surface and the entire lower surface of each glass cloth 10. This enables the relative permittivity to be substantially equalized over the entire surface of each glass cloth 10.

Thus, the difference between the relative permittivity near the POS wire 21 and the relative permittivity near the NEG wire 22 can be stably reduced unlike conventional wiring boards. Accordingly, the difference in delay between the POS signal and the NEG signal can be smaller than that in conventional wiring boards without limitations such as the arrangement of the differential signal wires 20 in accordance with the arrangement of the warp yarns 11 and the weft yarns 12 of the glass cloths 10 or the meander of the differential signal wires 20.

A simulation is carried out to investigate how much the difference between the relative permittivity near the POS wire 21 and the relative permittivity near the NEG wire 22 affects the difference in delay between the POS signal and the NEG signal and the insertion loss of the differential signal wires.

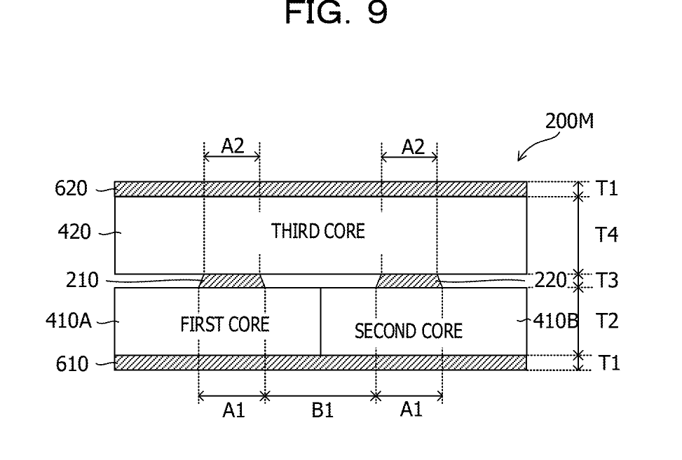

FIG. 9 is a sectional view of the structure of a model board 200M that is a simulation model. As illustrated in FIG. 9, ground planes 610 and 620 are formed as the bottom layer and the top layer of the model board 200M. The thickness T1 of the ground planes 610 and 620 is 32 μm. A first core 410A and a second core 410B are arranged in a row on the ground plane 610 of the bottom layer. The thickness T2 of the first core 410A and the second core 410B is 100 μm. A POS wire 210 is disposed on the first core 410A. A NEG wire 220 is disposed on the second core 410B. The length A1 of the bottom surfaces of the POS wire 210 and the NEG wire 220 is 84 μm, the length A2 of the top surfaces thereof is 68 μm, and the thickness T3 thereof is 32 μm. The distance B1 between the POS wire 210 and the NEG wire 220 is 172 μm. A third core 420 is disposed on the POS wire 210 and the NEG wire 220. The thickness T4 of the third core 420 is 102 μm. The ground plane 620 is formed on the third core 420.

In the model board 200M having the above structure, the relative permittivity of the first core 410A is a fixed value of 3.39. The relative permittivity of the third core 420 is a fixed value of 3.37. The relative permittivity of the second core 410B is changed by 0.5 at a time until the relative permittivity becomes 4.0 from 1.0. The simulation indicates the difference in delay between the POS signal and the NEG signal and the insertion loss of the differential signal wires in the case where the relative permittivity of the second core 410B is changed in the above manner. The result is illustrated in Table 1. The difference in delay corresponds to a difference in delay per wire length of 20 mm. The insertion loss corresponds to an insertion loss per wire length of 20 mm in the case where the frequency of the differential signal is 12.5 GHz. The dielectric tangent of the first core 410A and the second core 410B is determined to be 0.0024, and the dielectric tangent of the third core 420 is determined to be 0.0023 to obtain the insertion loss.

Table 1

TABLE 1

| | | | DIFFERENCE IN | INSERTION |
|---|---|---|---|---|
| THIRD CORE | FIRST CORE | SECOND CORE | DELAY BETWEEN | LOSS |
| RELATIVE | RELATIVE | RELATIVE | POS AND NEG | 12.5 GHZ |
| PERMITTIVITY | PERMITTIVITY | PERMITTIVITY | [ps/20 mm] | [dB/20 mm] |
| 3.37 | 3.39 | 4.0 | 4.74 | −0.62 |
| | | 3.5 | 0.86 | −0.45 |
| | | 3.0 | −3.70 | −0.50 |
| | | 2.5 | −7.21 | −0.80 |
| | | 2.0 | −11.39 | −1.37 |
| | | 1.5 | −15.94 | −2.35 |
| | | 1.0 | −19.91 | −3.67 |

As illustrated in Table 1, it can be confirmed that, when the relative permittivity of the first core 410A is substantially equal to the relative permittivity of the second core 410B, the difference in delay between the POS signal and the NEG signal is substantially zero. It can be also confirmed that the more the difference in the relative permittivity between the first core 410A and the second core 410B, the more the difference in delay between the POS signal and the NEG signal, and the more the insertion loss.

When the difference in the relative permittivity between the first core 410A and the second core 410B is about 0.5, the difference in delay between the POS signal and the NEG signal is about 4 ps. For example, when the bit rate of signal transmission is 25 Gbps, 1 UI (unit interval) is 40 ps. Accordingly, it can be understood that, when the bit rate of signal transmission is 25 Gbps, a slight difference of 0.5 between the relative permittivity of the first core 410A and the relative permittivity of the second core 410B results in the difference in delay that corresponds to 10% of 1 UI, and the quality of signal transmission is greatly affected.

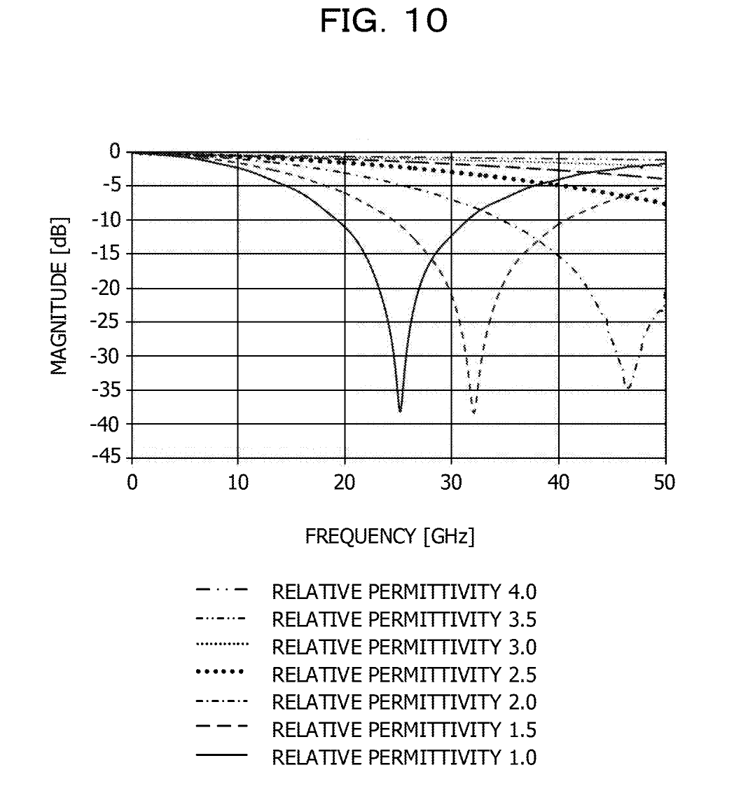

FIG. 10 is a graph illustrating frequency characteristics of the insertion loss that is obtained by the simulation for each relative permittivity of the second core 410B. When the difference in the relative permittivity between the first core 410A and the second core 410B increases, and the difference in delay between the POS signal and the NEG signal increases, the resonant frequency shifts to a low frequency side. Consequently, the insertion loss at, for example, 12.5 GHz increases. An increase in the insertion loss decreases an aperture of an eye pattern, and this is a cause of reduction in the quality of differential signal transmission.

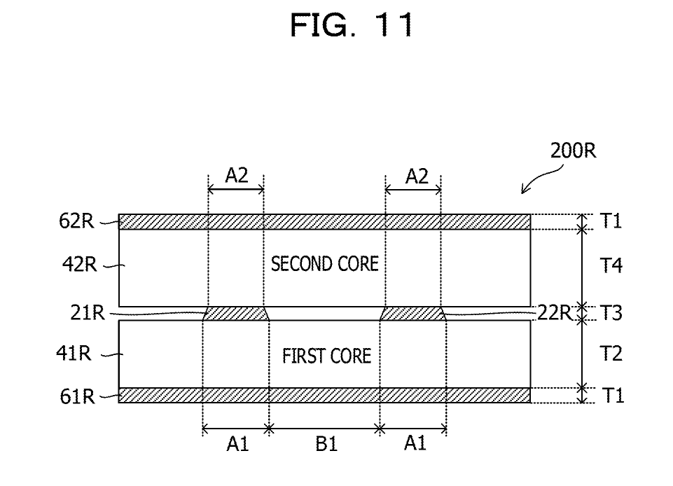

The difference in delay between the POS signal and the NEG signal in wiring boards manufactured by using a conventional technique was actually measured. FIG. 11 is a sectional view of the structure of a wiring board 200R for measurement that was manufactured.

As illustrated in FIG. 11, ground planes 61R and 62R were formed as the bottom layer and the top layer of the wiring board 200R for measurement. The thickness T1 of the ground planes 61R and 62R was 18 μm. A first core 41R was disposed on the ground plane 61R as the bottom layer. The thickness T2 of the first core 41R was 100 μm. A POS wire 21R and a NEG wire 22R were disposed on the first core 41R. The length A1 of the bottom surfaces of the POS wire 21R and the NEG wire 22R was 110 μm, the length A2 of the upper surfaces thereof was 90 μm, and the thickness T3 thereof was 18 μm. The distance B1 between the POS wire 21 and the NEG wire 22 was 170 μm. A second core 42R was disposed on the POS wire 21R and the NEG wire 22R. The thickness T4 of the second core 42R was 120 μm. The ground plane 62R was disposed on the second core 42R. The first core 41R and the second core 42R each contained a glass cloth (not illustrated). The positional relationships between the POS wire 21R and the glass cloth and between the NEG wire 22R and the glass cloth were not controlled and were random. The specified value of the relative permittivity of the first core 41R and the second core 42R was 3.8. The specified value of the dielectric tangent was 0.005.

Four wiring boards 200R for measurement were manufactured such that the lengths of the POS wire 21R and the NEG wire 22R were 5 cm, 10 cm, 15 cm, 20 cm, 25 cm, 30 cm, 35 cm, 40 cm, 45 cm, 50 cm, 60 cm, and 70 cm.

The difference in delay between the POS signal and the NEG signal in the manufactured wiring boards 200R for measurement was actually measured. The result is illustrated in Table 2.

TABLE 2

| | |
|---|---|
| | DIFFERENCE IN DELAY |
| WIRE LENGTH | BETWEEN POS AND NEG [ps] |

| [cm] | 1 | 2 | 3 | 4 |
|---|---|---|---|---|
| 5 | 9.6 | 1.6 | 1.3 | 8.1 |
| 10 | 9.3 | 0.6 | 0.0 | 3.5 |
| 15 | 20.4 | 6.7 | 13.6 | 20.6 |
| 20 | 6.6 | 12.1 | 21.1 | 0.0 |
| 25 | 5.5 | 13.7 | 24.8 | 5.5 |
| 30 | 23.0 | 18.0 | 26.4 | 14.7 |
| 35 | 9.5 | 28.7 | 42.1 | 9.4 |
| 40 | 0.0 | 4.3 | 32.7 | 13.0 |
| 45 | 17.0 | 19.4 | 29.2 | 17.0 |
| 50 | 29.8 | 24.3 | 5.4 | 5.4 |
| 60 | 38.7 | 6.4 | 48.6 | 6.4 |
| 70 | 7.5 | 3.8 | 30.2 | 41.5 |

As illustrated in Table 2, there is no correlation between the lengths of the POS wire 21R and the NEG wire 22R and the difference in delay. The reason is presumably that the positional relationships between the POS wire 21R and the glass cloth and between the NEG wire 22R and the glass cloth were random, and the difference between the relative permittivity near the POS wire 21R and the relative permittivity near the NEG wire 22R varied among the wiring boards. Thus, it is difficult for the wiring boards manufactured by using the conventional technique to control the difference between the relative permittivity near the POS wire 21R and the relative permittivity near the NEG wire 22 and to stably reduce the difference in delay between the POS signal and the NEG signal to an acceptable level.

In contrast, in the wiring board 100 according to the embodiment, the glass powders disperse in the stitches 13 of the glass cloths 10. This enables the difference between the relative permittivity near the POS wire 21 and the relative permittivity near the NEG wire 22 to be stably reduced, and enables the difference in delay between the POS signal and the NEG signal to be stably reduced to an acceptable level.

In an example described according to the embodiment, glass is used as a powder material that spreads over the upper surface and the lower surface of each glass cloth 10. However, the material is not limited thereto. A powder of a material having a relative permittivity more than the relative permittivity of the thermosetting resins 30 included in the cores 41 and 42 can be used instead of the glass powder. The relative permittivity of the powder material that spreads over the upper surface and the lower surface of each glass cloth 10 is preferably no less than 0.6 times the relative permittivity of the glass of which the glass fibers 10a are formed and no more than 1.4 times the relative permittivity of the glass of which the glass fibers 10a are formed. Examples of such a material include a phenol resin (relative permittivity of 4.0 to 6.0), a urea resin (relative permittivity of 6.0 to 8.0), and a melamine resin (7.2 to 8.4). Powders of these resin material can be used instead of the glass powder.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A wiring board comprising:
a core; and
a differential signal wire disposed on a surface of the core,
wherein the core includes a glass cloth formed such that a warp yarn and a weft yarn that are each formed of a glass fiber are woven, a resin in which the glass cloth is embedded, and a powder that disperses in a stitch of the glass cloth that is surrounded by the warp yarn and the weft yarn and that is formed of a material having a relative permittivity more than a relative permittivity of the resin.

2. The wiring board according to claim 1,
wherein the powder spreads over an entire upper surface and an entire lower surface of the glass cloth.

3. The wiring board according to claim 1,
wherein the powder is a glass powder.

4. The wiring board according to claim 1,
wherein the warp yarn and the weft yarn each contain bundles of glass fibers, and
wherein a particle diameter of the powder is smaller than a diameter of each of the glass fibers.

5. The wiring board according to claim 1,
wherein a relative permittivity of the powder is no less than 0.6 times a relative permittivity of the glass fiber and no more than 1.4 times the relative permittivity of the glass fiber.

6. The wiring board according to claim 1,
wherein the powder is a phenol resin powder, a urea resin powder, or a melamine resin powder.

7. A wiring board comprising:
a first core;
a second core; and
a differential signal wire disposed between the first core and the second core,
wherein the first core and the second core each include a glass cloth formed such that a warp yarn and a weft yarn that are each formed of a glass fiber are woven, a resin in which the glass cloth is embedded, and a powder that disperses in a stitch of the glass cloth that is surrounded by the warp yarn and the weft yarn and that is formed of a material having a relative permittivity more than a relative permittivity of the resin.

8. The wiring board according to claim 7,
wherein the powder spreads over an entire upper surface and an entire lower surface of the glass cloth.

9. The wiring board according to claim 7,
wherein the powder is a glass powder.

10. The wiring board according to claim 7,
wherein the warp yarn and the weft yarn each contain bundles of glass fibers, and
wherein a particle diameter of the powder is smaller than a diameter of each of the glass fibers.

11. The wiring board according to claim 7,
wherein a relative permittivity of the powder is no less than 0.6 times a relative permittivity of the glass fiber and no more than 1.4 times the relative permittivity of the glass fiber.

12. The wiring board according to claim 7,
wherein the powder is a phenol resin powder, a urea resin powder, or a melamine resin powder.

13. A method of manufacturing a wiring board comprising:
spreading a first powder over a surface of a first resin;
disposing, on the first powder, a glass cloth formed such that a warp yarn and a weft yarn that are each formed of a glass fiber are woven;
spreading a second powder over a surface of the glass cloth such that the second powder disperses in a stitch of the glass cloth that is surrounded by the warp yarn and the weft yarn;
disposing a second resin on the second powder; and
forming a differential signal wire on a surface of the first resin or the second resin,
wherein the first powder and the second powder are each formed of a material having a relative permittivity more than a relative permittivity of the first resin and the second resin.

14. The method according to claim 13,
wherein each of the first powder and the second powder is a glass powder.

15. The method according to claim 13,
wherein the warp yarn and the weft yarn each contain bundles of glass fibers, and
wherein a particle diameter of the first powder and the second powder is smaller than a diameter of each of the glass fibers.

16. The method according to claim 13,
wherein the first powder is spread over the surface of the first resin after the first resin is semi-cured.

17. The method according to claim 13,
wherein a relative permittivity of the first powder and the second powder is no less than 0.6 times a relative permittivity of the glass fiber and no more than 1.4 times the relative permittivity of the glass fiber.

18. The method according to claim 13,
wherein each of the first powder and the second powder is a phenol resin powder, a urea resin powder, or a melamine resin powder.
